(19) United States
(12) Patent Application Publication
(10) Pub. No.: US 2025/0089409 A1
(43) Pub. Date: Mar. 13, 2025

(54) DISPLAY PANEL AND DISPLAY DEVICE

(71) Applicants: BOE MLED TECHNOLOGY CO., LTD., Beijing (CN); BOE TECHNOLOGY GROUP CO., LTD., Beijing (CN)

(72) Inventors: Heling Zhu, Beijing (CN); Bing Zhang, Beijing (CN); Xuerong Wang, Beijing (CN); Haiwei Sun, Beijing (CN); Ming Zhai, Beijing (CN)

(73) Assignees: BOE MLED TECHNOLOGY CO., LTD., Beijing (CN); BOE TECHNOLOGY GROUP CO., LTD., Beijing (CN)

(21) Appl. No.: 18/287,905

(22) PCT Filed: Nov. 25, 2022
(86) PCT No.: PCT/CN2022/134374

§ 371 Date: Oct. 23, 2023

(51) Int. Cl. H01L 33/50; H01L 25/075; H01L 33/54; H01L 33/56

(52) U.S. Cl. CPC H10H 20/8514; H01L 25/0753; H10H 20/8512; H10H 20/853; H10H 20/854

(57) ABSTRACT

The present disclosure provides a display panel and a display device. The display panel includes a substrate, a light-emitting layer located at a side of the substrate, and an encapsulation layer located at s side of the light-emitting layer facing away from the substrate; the light-emitting layer comprises a plurality of light-emitting elements, and the encapsulation layer comprises a cut-off filter film layer, wherein the plurality of the light-emitting elements generate emitted light of at least two colors; wherein, the cut-off filter film layer comprises a plurality of filter areas, and one filter area filters the emitted light of one color, so that a wavelength range of the emitted light transmitting through the filter area is narrower than that of emergent light.

### TECHNICAL FIELD

The present disclosure relates to the technical field of display and, more particularly, to a display panel and a display device.

### BACKGROUND

In the fields of display products, before the display products leave the factory, the display quality of the display products needs to be tested, and the qualified display product is allowed to flow into a client. Wherein, the display quality includes color uniformity and brightness consistency of a display picture.

In the related art, in order to make the display quality of the display product qualified, before encapsulation, the display products will be classified by Bin, which refers to the sort of light-emitting elements (also known as light-emitting chips, for example a Light-Emitting Diode (LED) chip) used before encapsulation, to classify chips of the same quality level into one grade, that is, the same Bin level.

However, with the continuous upgrading of display products, their own functions and characteristics are constantly improved, and the requirements for display quality are also increasing. Under this background, it is necessary to improve the fineness of Bin classification. In this way, more Bin levels need to be classified when performing Bin classification. For example, a plurality of chips that were classified as one grade in the past may have to be classified into more finer Bin levels again, so that causing the difficulty of the Bin classification is greatly increased.

### SUMMARY

The present disclosure provides a display panel, including:
a substrate, a light-emitting layer located at a side of the substrate, and an encapsulation layer located at a side of the light-emitting layer facing away from the substrate; the light-emitting layer includes a plurality of light-emitting elements, and the encapsulation layer includes a cut-off filter film layer; wherein the plurality of the light-emitting elements generate emitted light of at least two colors;
wherein, the cut-off filter film layer includes a plurality of filter areas, and one filter area filters the emitted light of one color, so that a wavelength range of the emitted light transmitting through the filter area is narrower than that of emergent light.

According to some alternative embodiments, the wavelength range of the emergent light of every color transmitting through the cut-off filter layer is a range in which a difference from the central wavelength of the emitted light of this color is less than or equal to 15 nm.

According to some alternative embodiments, the orthogonal projection of the cut-off filter film layer on the substrate covers the substrate completely.

According to some alternative embodiments, the orthogonal projections of the plurality of filter areas on the substrate do not overlap with each other.

According to some alternative embodiments, the orthographic projection of one of the plurality of filter areas on the substrate covers the orthographic projection of at least one of the plurality of light-emitting elements generating a same color on the substrate, to make the filter area filters the emitted light emitted by the light-emitting elements that covered by the filter area.

According to some alternative embodiments, a space exists between orthographic projections of the two adjacent filter areas on the substrate.

According to some alternative embodiments, the cut-off filter film layer includes a plurality of sub-film layers disposed in a stacking manner, and every two adjacent sub-film layers have refractive indexes of different magnitudes.

According to some alternative embodiments, in the two adjacent sub-film layers, a refractive index of one sub-film layers is larger than 2, and a refractive index of the other sub-film layer is less than 2.

According to some alternative embodiments, in the two adjacent sub-film layers, the film material of one sub-film layers includes at least one of Ta₂O₅, TiO₃, TiO₂ and ZrO₂, and the film material of the other sub-film layer includes at least one of SiO₂, MgF₂, CeF₃, Al₂O₃ and Y₂O₃.

According to some alternative embodiments, the cut-off filter film layer includes a first film layer material and a second film layer material with different refractive indexes, wherein one sub-film layer in every two adjacent sub-films is the first film layer material, and the other sub-film layer in every two adjacent sub-films is the second film layer material.

According to some alternative embodiments, the first film material includes Ta₂O₅, and the second film material includes SiO₂.

According to some alternative embodiments, a number of the plurality of sub-film layers is larger than or equal to 9 and less than or equal to 16.

According to some alternative embodiments, in every two colors of emitted light, a number of the sub-film layers in the filter area corresponding to the emitted light with a longer wavelength is larger than a number of the sub-film layers in the filter area corresponding to the emitted light with a shorter wavelength.

According to some alternative embodiments, the different sub-film layers have different thicknesses.

According to some alternative embodiments, in every two colors of the emitted light, the thickness of the filter area corresponding to the emitted light with a longer wavelength is larger than that of the emitted light with a shorter wavelength.

According to some alternative embodiments, the encapsulation layer further includes a composite adhesive layer located at a side of the light-emitting layer facing away from the substrate, and the cut-off filter film layer is located between the composite adhesive layer and the light-emitting layer, or located at a side of the composite adhesive layer facing away from the light-emitting layer.

According to some alternative embodiments, the composite adhesive layer includes at least one of a diffusion adhesive layer, a transparent adhesive layer and a black adhesive layer; wherein, under the condition that the composite adhesive layer includes the diffusion adhesive layer, the diffusion adhesive layer is disposed close to the light-emitting layer.

According to some alternative embodiments, the plurality of light-emitting elements include a light-emitting element that emits blue light, a light-emitting element that emits green light and a light-emitting element that emits red light.

According to some alternative embodiments, the light-emitting element is a submillimeter light-emitting diode.

The present disclosure further provides a display device including the display panel described in any one or more of the above-mentioned embodiments.

The display panel provided by the present disclosure includes a substrate, a light-emitting layer and an encapsulation layer, wherein the encapsulation layer may encapsulate the light-emitting layer, and the encapsulation layer includes a cut-off filter film layer, the cut-off filter film layer is configured to allow filtering of the emitted light emitted by the light-emitting layer, so that the wavelength range of the emergent light transmitting through the cut-off filter film layer is smaller than that of the emitted light.

Since the cut-off filter film allows the light of the light-emitting element to transmitted through, and the wavelength range of the emergent light after transmitting through this film is compressed. In this way, the difference between the wavelengths of the light emitted by the light-emitting element after transmitting through is narrower, that is, the wavelength range is compressed, so that the color purity and color uniformity of the light emitted from the display panel are improved. In this way, the following advantages are brought:

On the one hand, the requirement for the wavelength range of light emitted by the light-emitting element is reduced, and the wavelength range of the light emitted by the light-emitting element may be allowed to be wider. Consequently, even though the light-emitting element is performed bin classification with a relative coarse granularity and has a wider wavelength range, the wavelength range may be limited to a smaller range via the cut-off filter film layer in the encapsulation layer during later encapsulating, and the color purity and uniformity of the display panel are improved, so that the display quality of the display panel may still be ensured when the light-emitting element is performed bin classification with a relative coarse granularity. That is, by adopting the encapsulation layer provided in the present disclosure, the bin classification with a relative coarse granularity may be allowed, and the fineness of the bin classification may be reduced, so that the problem that the increased difficulty of the Bin classification is avoided.

On the other hand, since the requirement on the fineness of the bin classification may be reduced, consequently, the bin classification with a relative coarse granularity may be allowed, so that the utilization rate of the light-emitting element is improved, and the light-emitting element that is discarded and recycled in the light-emitting elements produced in a same batch is greatly reduced, so that production cost is reduced.

The above description is merely a summary of the technical solutions of the present disclosure. In order to more clearly understand the technical means of the present disclosure to enable the implementation according to the content of the description, and to make the above-mentioned and other purposes, features and advantages of the present disclosure more apparent and understandable, the particular embodiments of the present disclosure are provided below.

### BRIEF DESCRIPTION OF THE DRAWINGS

In order to more clearly illustrate the technical solutions of the embodiments of the present disclosure or the related technologies, the figures that are required to describe the embodiments or the related technologies will be briefly introduced below. Apparently, the figures that are described below are some embodiments of the present disclosure, and a person skilled in the art may obtain other figures according to these figures without paying creative work. It should be noted that, the proportion in the drawings is merely indicative and does not represent actual proportion.

FIG. 1 schematically shows a structural schematic diagram of the display panel of the present disclosure.

FIG. 2 schematically shows a cross-sectional structural schematic diagram of the display panel in some embodiments.

FIG. 3 schematically shows a cross-sectional structure schematic diagram of the display panel in some other embodiments.

FIG. 4 schematically shows a top view schematic diagram of the display panel shown in FIG. 2.

FIG. 5a schematically shows a top view of the display panel.

FIG. 5b schematically shows a top view of another display panel.

FIG. 6 schematically shows a top view of the display panel shown in FIG. 3.

FIG. 7 schematically shows a schematic diagram of the light filtering process of the cut-off filter film layer.

FIG. 8 schematically shows an arrangement diagram of the thickness and materials of each of the sub-film layers in the whole cut-off filter film layer.

FIG. 9 schematically shows an arrangement histogram of the thickness and materials of each of the sub-film layers in the whole cut-off filter film layer.

FIG. 10 schematically shows a schematic diagram of the light transmittance after transmitting through the whole cut-off filter film.

FIG. 11 schematically shows an arrangement diagram of the thickness and materials of each of the sub-film layers in the filter area for filtering blue light in the cut-off filter film layer;

FIG. 12 schematically shows a schematic diagram of the light transmittance after via the filter area for filtering blue light.

FIG. 13 schematically shows an arrangement diagram of the thickness and materials of each of the sub-film layers in the filter area for filtering green light in the cut-off filter film layer;

FIG. 14 schematically shows a schematic diagram of the light transmittance after via the filter area for filtering green light.

FIG. 15 schematically shows an arrangement diagram of the thickness and materials of each of the sub-film layers in the filter area for filtering red light in the cut-off filter film layer.

FIG. 16 schematically shows a schematic diagram of the light transmittance after via the filter area for filtering red light.

### DRAWING SYMBOLS

101—substrate, 102—light-emitting layer, 1021—light-emitting element, 103—cut-off filter film layer, 104—second substrate layer, 105—diffusion adhesive layer, 106—transparent adhesive layer, 107—black adhesive layer, 108—first substrate layer, 201—composite adhesive layer, 1031—red light filter area. 1032—green light filter area, 1033—blue light filter area, R—red, G—green, B—blue.

### DETAILED DESCRIPTION

In order to make the purposes, the technical solutions and the advantages of the embodiments of the present disclosure more clearly, the technical solutions of the embodiments of the present disclosure will be clearly and completely described below with reference to the drawings of the embodiments of the present disclosure. Apparently, the described embodiments are merely certain embodiments of the present disclosure, rather than all of the embodiments. All of the other embodiments that a person skilled in the art obtains on the basis of the embodiments of the present disclosure without paying creative work will fall within the protection scope of the present disclosure.

In the field of display, in order to ensure display quality, in the process of Bin classification, chips with wavelength distribution within 2 nm and brightness change controlled within 15% may be classified into one grade, that is, a same Bin level. In practice, the chips will be tested and classified according to wavelength, light-emitting intensity, voltage, and so on, and the chips will be classified into more Bins and categories, and a Bin classification apparatus is capable to automatically pack the chips into different bin boxes according to a set test standard. Due to the increasingly high requirements for LED Bin classification, the classified Bin levels are also increasing, and the Bin classification apparatus has increased from 32 bins to 64 bins, but it still incapable to satisfy the requirements of production and market.

Generally speaking, the difficulty of Bin classification is not merely related to the refinement requirements (bin level) of Bin classification, but also related to the size of a chip. The smaller the chip size, the larger the difficulty of Bin classification. For example, for micro-sized display products such as a Micro light-emitting diode (LED), the refinement requirements are more stringent, and the test may be completed merely by using a probe. The sorting process requires an accurate machinery and an image recognition system, which generates an extremely high requirement for the test apparatus and the test precision.

In the related technology, in order to satisfy the increasingly refinement Bin classification requirements and deal with the increasingly difficult Bin classification, generally, it is more focused on the research and development of apparatus for refinement Bin classification, so that the Bin level is managed and controlled more refinement to satisfy the requirements. However, the apparatus for refinement Bin classification is expensive and requires higher cost. Especially for micro-sized display products, for example a micro-LED, more refinement Bin classification apparatus are required, and costs are higher.

Furthermore, since the increasingly higher requirements for the refinement of Bin classification, it is increasingly higher difficult to classify Bin, which not merely causes a low efficiency of Bin classification of products in a same batch, but also causes a large number of chips are discarded due to high refinement requirements, so that the production yield is greatly reduced, and forcing manufacturers to re-produce chips, thus the production cost is increased.

In view of this, the present disclosure proposes a solution to solve the above-mentioned technical problems in whole or in part. The core of this solution lies in: the wavelength range of light emitted by the light-emitting element is compressed by means of the encapsulation layer of the display panel, that is, the wavelength range of the emergent light is limited, so that the wavelength range of light emitted by the light-emitting element is narrower after transmitting through the encapsulation layer, so that an effect of high color uniformity is achieved and the display quality is improved.

Particularly, it may be realized by configuring a cut-off filter film layer in the encapsulation layer, the cut-off filter film layer allows the light of the light-emitting element to be transmitted through and is configured to filter the emitted light emitted by the light-emitting layer, to make a wavelength range of the emitted light transmitting through the cut-off filter film layer is narrower than that of the emitted light. That is, the wavelength range of light emitted by a plurality of light-emitting elements is narrowed after transmitting through the cut-off filter film, so that allowing the sorted light-emitting element to emit light in a wider wavelength range.

The display panel proposed in the present disclosure will be introduced below.

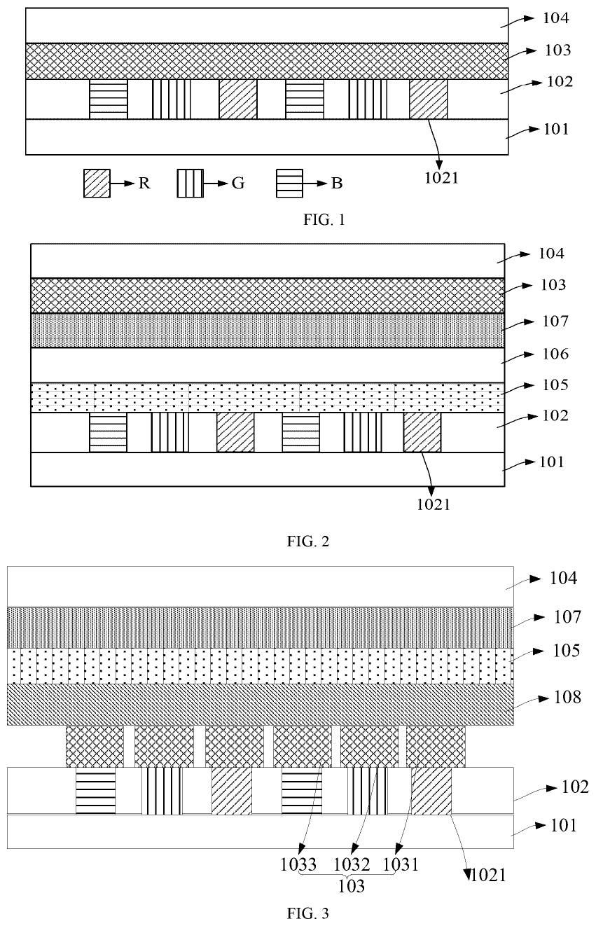

Referring to FIG. 1, showing a structural schematic diagram of the display panel of the present disclosure. As shown in FIG. 1, the display panel may particularly include the following structures:
a substrate 101, a light-emitting layer 102 located at a side of the substrate 101, and an encapsulation layer located at a side of the light-emitting layer 102 facing away from the substrate 101. Wherein, the light-emitting layer 102 includes a plurality of light-emitting elements 1021, and the encapsulation layer includes a cut-off filter film layer 103.

Wherein the plurality of the light-emitting elements 1021 generate emitted light of at least two colors. That is, at least two colors of emitted light may be generated in the light-emitting layer, wherein one light-emitting element 1021 generates one color of emitted light, and among the plurality of light-emitting elements, some light-emitting elements 1021 may generate one color of emitted light, and some light-emitting elements may generate the other color of emitted light.

Wherein, the cut-off filter film layer 103 is configured to filter the emitted light emitted by the light-emitting layer 102, so that a wavelength range of the emitted light transmitting through the cut-off filter film layer 103 is narrower than that of the emitted light.

In the FIG. 1, Red (R), G (green) and blue (B) represent the colors of the emitted light emitted by the corresponding light-emitting elements.

In the present disclosure, the substrate 101 may be made of glass, and its thickness may be set to be 0.5 millimeter (mm), and the substrate 101 may be used as a load-bearing component of the light-emitting element 1021. The front surface of the substrate 101 (a surface of the substrate 101 close to the light-emitting element 1021) is a metal wiring of a LED driving circuit, and the side edge and the back surface are the bonding COF (Chip On Flex, or, Chip On Film). In practice, the substrate may also be made of other materials, for example Printed Circuit Board (PCB) materials.

A plurality of light-emitting elements 1021 are arranged in an array in the light-emitting layer 102, and a barrier layer may or may not be disposed in a gap between the light-emitting elements 1021. Particularly, an encapsulation layer may be disposed above the light-emitting layer 102. On the one hand, the encapsulation layer protects the light-emitting layer 102, so that the light-emitting element 1021 in the light-emitting layer 102 is not damaged or exposed. On the other hand, the encapsulation layer 102 may also support the light-emitting layer 102.

It should be noted that, the encapsulation layer may allow the emitted light emitted by the light-emitting layer 102 to transmit through, to realize the display function of the display panel. Particularly, as described above, in order to reduce the bin classification fineness of the light-emitting element 1021, the encapsulation layer may be improved, so that the wavelength range of the emergent light may be narrowed after the emitted light emitted by the light-emitting layer 102 is transmitted via the encapsulation layer.

In practice, a cut-off filter film 103 may be configured in the encapsulation layer, this cut-off filter film 103 has a light filtering function, and light in one wavelength range may be allowed to transmit through, but light outside the wavelength range is not allowed to transmit through, so that the wavelength range of the emergent light after transmitting through the cut-off filter film 103 is narrower than that of the emitted light, making the emergent light more pure, and so that the quality of color display is better.

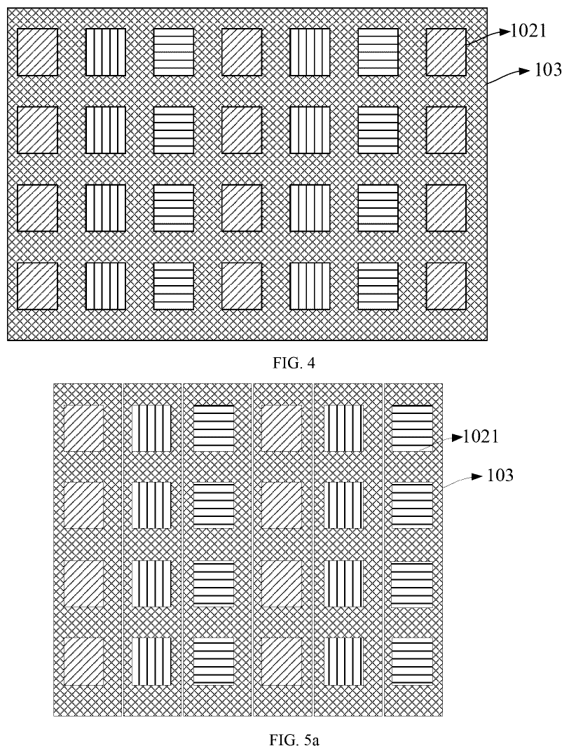

According to some embodiments, the light-emitting layer 102 may emit light of a plurality of colors, wherein every color corresponds to one wavelength range, for example, the wavelength range of red light is generally 625 nm to 740 nm, the wavelength range of blue light is generally 400 nm to 480 nm, and the wavelength range of green light is generally 492 nm to 577 nanometer (nm).

Wherein, when the light-emitting layer 102 emits a plurality of colors of the emitted light, the cut-off filter film layer 103 may filter the emitted light of every color in a targeted manner, so that narrowing the wavelength range of the emergent light of every color is narrowed. Particularly, the cut-off filter film layer 103 includes a plurality of filter areas, and one filter area is configured to filter the emitted light of one color. As shown in FIG. 3, the cut-off filter film layer 103 includes a red light filter area 1031, a green light filter area 1032 and a red light filter area 1033. In this way, a wavelength range of the emergent light transmitting through every filter area is narrower than that of the emitted light of one color the filter area aiming at. According to the position of the light-emitting element 1021, a plurality of filter areas may be provided, so that every filter area covers a light-emitting element of one color.

For example, the light-emitting layer 102 emits green light and red light. In this case, the light-emitting elements 1021 include a chip emitting red light and a chip emitting green light. Particularly, it is assumed that the wavelength range of emitted red light is between 650 nm and 700 nm, and the wavelength range of emitted green light is between 525 nm and 570 nm. Thereafter, the filter area corresponding to the red light in the cut-off filter film layer 103 may be configured to allow the red light between 660 nm and 690 nm to transmit through, but does not allow the red light of other wavelengths to transmit through. The filter area corresponding to green light allows the green light between 540 nm and 570 nm to transmit through, but does not allow the green light of other wavelengths to transmit through.

In this way, after via the encapsulation layer, the wavelengths of the transmitted red light are all distributed within a range of 15 nm from the central wavelength of 675 nm, and the wavelengths of the transmitted green light are all distributed within a range of 15 nm from the central wavelength of 555 nm. Consequently, even though the wavelength range of the light-emitting element 1021 emitting red light and green light is wider, the purity of the red light and green light may still be improved after transmitting through the encapsulation layer, and the display quality may be ensured. Further, in the process of Bin classification, it may allow the fineness requirement for the waveband range of the light-emitting element 1021 of every light-emitting color to be reduced, so that the Bin classification difficulty is reduced.

Wherein, the configuration of the filter areas for filtering different colors may be different or may be the same. The configuration may include the material, thickness and size of the filter areas in the plane direction of the substrate.

Certainly, according to some other embodiments, the cut-off filter film layer used in the present disclosure is adopted without excluding in the case that the light-emitting layer emits one color of emitted light. In this case, under the condition that the light-emitting layer 102 emits light of one color, the cut-off filter film layer 103 may filter the emitted light of this color, so that the wavelength range of the emergent light is narrowed. For example, the light-emitting layer 102 emits red light, that is, red light is emitted by the light-emitting element 1021, and the wavelength range of the emitted red light is between 650 nm and 700 nm. The cut-off filter layer 103 may be configured to allow the red light between 660 nm and 690 nm to transmit through, but the red light with other wavelengths is not allowed to transmit through. After via the encapsulation layer, the wavelengths of the transmitted red light are all distributed within 15 nm of the central wavelength of 675. Consequently, even though the wavelength range of the red light emitted by the light-emitting element 1021 is wider, the purity of the red light may be improved after transmitting through the encapsulation layer, and so that the display quality may be ensured. That is, in the process of Bin classification, the fineness requirement of the waveband range of the light-emitting element 1021 may be reduced, so that the difficulty of Bin classification is reduced.

Certainly, when the light-emitting layer 102 emits light of one color, a plurality of filter areas may be provided according to the distribution areas of the light-emitting elements 1021. For example, every a adjacent light-emitting elements 1021 corresponds to one filter area. In this case, every display area may be filtered in a targeted manner. For example, in some large-sized display panels, it is often necessary to design a plurality of areas that are capable to display pictures, for example a large-sized rectangular display panel, four display areas may be designed, and data of different sources may be displayed. In this case, the arrangement of the light-emitting elements 1021 in the light-emitting layer 102 may be adaptively arranged into four areas. Accordingly, the cut-off filter film layer 103 may be divided into four filter areas.

Certainly, the above is merely an exemplary explanation, wherein the light-emitting element 1021 may also include chips that generate other colors, for example purple, yellow, white, and so on. For the light-emitting elements 1021 with other light-emitting colors, the encapsulation layer of the present disclosure is still applicable, that is, the purity of other colors may still be improved through the encapsulation layer.

The operation principle of the cut-off filter film layer 103 is as follows:

When the thickness of the cut-off filter films 103 is appropriate, the optical path of the light reflected on the two surfaces of the film is exactly equal to half a wavelength, so that the light is counteracted with each other, which greatly reduces the reflection loss of light and enhances the intensity of transmitted light. When light is incident from a medium having a refractive index of at to a medium having a refractive index of n1, light will be reflected on the interface between the two media. If the medium does not absorb light, the interface is an optical surface, and the light is vertically incident, thereafter the reflectivity R satisfies the following relational expression (I):

R=(n0−n1)²/(n0+n1)² relational expression (I);

The light transmittance of the cut-off filter film layer 103 is T=1−R;

The refractive index of the cut-off filter film layer 103 satisfies the following relation (2):

nd=¼λ relational expression (II);
wherein n is the refractive index of the film, d is the thickness of the film, and λ is the wavelength.

It may be seen that, under the condition that the wavelength range of the emitted light is known, the required refractive index of the film may be achieved by designing the thickness and material of the film, and the reflectivity of light with a certain wavelength may be controlled by this relational expression (I), so that the light is totally reflected or transmits through, consequently, the above-mentioned filtering function is realized.

An example is given to illustrate the advantages of this disclosure:

It is assumed that, a batch of light-emitting elements 1021 that emitting red light is 10,000, the wavelength range of the red light emitted by the display panel needs to be limited between 670 nm and 680 nm (including the wavelength at the endpoint). It is assumed that, 6000 of the 10,000 light-emitting elements 1021 satisfy this condition.

By adopting the related technology of Bin classification, 10,000 light-emitting elements 1021 will be performed Bin classification according to a granularity of every 10 nm or Sum or even smaller, and one or more bin level chips will be selected for encapsulating. Since the wavelength range of the required emitted red light is 670 nm to 680 nm, the light-emitting elements 1021 belong to every bin level in 670 nm to 680 nm will be used for subsequently encapsulating. That is, at least 4000 light-emitting elements 1021 may be discarded according to the related technology of the Bin classification (more may be discarded due to binning errors of Bin classification, and so on).

However, according to the present disclosure in the subsequent encapsulation stage, the cut-off filter film layer 103 will be disposed in the encapsulation layer. Consequently, when the encapsulation solution of the present disclosure is adopted, at the preorder Bin classification stage, Bin classification may be performed according to a granularity of 20 nm or even large. Assuming that chips with wavelengths ranging from 650 μm to 700 nm may be classified into a bin level according to this granularity, and assuming that 8,000 chips have wavelengths ranging from 650 nm to 700 nm, so that 8,000 chips may be used for subsequent encapsulation. In this way, the fineness of Bin classification is reduced, and fewer chips will be discarded.

Subsequently, in the encapsulation stage, the light-emitting layer 102 includes 8000 light-emitting elements 1021 emitting red light having a wavelength range of which is 650 nm to 700 nm, and the selected center wavelength is 675 nm. Assuming that the wavelength range of the red light that needs to transmit through the cut-off filer film layer 103 within a range in which a difference from 675 nm is less than or equal to Sam, the wavelength range of red light that transmits through the cut-off filter film layer 103 is 670 nm to 680 nm. Among the 8,000 light-emitting elements 1021 that emit red light, 6,000 light-emitting elements 1024 emit red light with a wavelength range of 670 nm to 680 nm. In this way, 2,000 light-emitting elements 1021 that reflect red light in other wavebands are allowed to be encapsulated into a display panel. That is, at the preorder Bin classification stage, even though the light-emitting elements 1021 have a wavelength range of 650 nm to 700 nm are classified into one Bin level, the display quality of the display panel will not be affected subsequently.

By adopting the technical solution of the embodiment of the present disclosure, on the one hand, the wavelength range of the light emitted by the light-emitting element 1021 may be allowed to be wider, so that even though the light-emitting element 1021 is performed with a coarse granularity Bin classification and has a wider wavelength range, the wavelength range may be limited to a narrower range via the cut-off filter film layer 103 in the encapsulation layer during later encapsulation, and the color purity and uniformity of the display panel may be improved, thus ensuring that when the light-emitting element 1021 is performed with coarse granularity Bin classification, the display quality of the display panel may still be guaranteed. In this way, the fineness of Bin classification is reduced and the difficulty of increased Bin classification is avoided, so that among the light-emitting elements 1021 produced in a same batch, the light-emitting elements 1021 are discarded and recycled during Bin classification process are greatly reduced, and the production cost is reduced and the product yield Product yield is facilitated.

On the other hand, the cut-off filter film layer 103 may include a filter area designed for every color of the light-emitting element 1021. That is, the cut-off filter film layer 103 for every color may be designed separately, so that the wavelength of every color of light may be screened by the corresponding cut-off filter film layer 103. In this way, the pertinence and accuracy of the screening of every color of light may be improved, so that the wavelength of the transmitted light of every color is within a preset waveband range corresponding to this color of light.

In some embodiments, the light-emitting element 1021 may be a light-emitting Diode (LED) chip 1021. Further, in some embodiments, the light-emitting element 1021 may be a submillimeter light-emitting diode, particularly, a Mini light-emitting element 1021 or a Micro light-emitting element 1001. Wherein, the Mini light-emitting element 1021 is between traditional LED and Micro LED, and its size is generally 100 μm˜300 μm. The Micro light-emitting element 1021 may be as small as 50 μm in size and about 0.002 inch in diameter, which is a micron-sized chip.

In these embodiments, the display panel may be a mini-LED display panel or a Micro LED display panel. For Mini light-emitting elements or Micro light-emitting elements, it is very difficult to be performed Bin classification because of their small size, so it is particularly necessary to reduce the difficulty of the Bin classification of these light-emitting elements 1021. When the encapsulation layer proposed in the present disclosure is adopted in a mini-LED display panel or a Micro LED display panel, the light-emitting waveband of the sub-millimeter light-emitting diode may be performed Bin classification with a wider waveband by means of the filtering function of the encapsulation layer, so that the difficulty of the Bin classification of the micro-LED display technology is greatly reduced.

In some embodiments, the light-emitting layer 102 may emit emitted light of at least one color. For example, emits green light and blue light, or emits red light and blue light, or emits green light and red light, or emits all the three colors. In some other embodiments, the light-emitting layer 102 may emit emitted light of a single color, for example, emit red light, blue light or green light.

In some embodiments, the plurality of light-emitting elements 1021 may include a light-emitting element 1021 that emitting blue light, a light-emitting element 1021 that emitting green light and a light-emitting element. 1021 that emitting red light, so that the light-emitting layer 102 may emit red light, green light and blue light.

The light-emitting element 1021 emits blue light, the light-emitting element 1021 emits green light and the light-emitting element 1021 emits red light may be arranged in an array in the light-emitting layer 102. Particularly, the light-emitting elements 1021 emit a same color light may be arranged in a row. In this case, the light-emitting elements in every adjacent row emit different colors. For example, the light-emitting elements in one row all emit blue light, and the light-emitting elements in the other row all emit green light, as shown in FIG. 5b. Alternatively, the light-emitting elements 1021 emit the same color light may be arranged in a column. In this case, the light-emitting elements in every adjacent column emit different colors. For example, the light-emitting elements in one column all emit blue light and the light-emitting elements in the other column all emit green light. In this case, referring to FIG. 5a.

In the display panel, a light-emitting element 1021 emits blue light, a light-emitting element 1021 emits green light and a light-emitting element 1021 emits red light may form a pixel unit, and every light-emitting element 1021 in this pixel unit may be called a sub-pixel. For example, a light-emitting element 1021 emits blue light may be a sub-pixel.

In some embodiments, the wavelength range of the emergent light of every color transmits through the cut-off filter layer 103 satisfies the following condition: it is a range in which a difference from the central wavelength of the emitted light of this color is less than or equal to 15 nm.

The central wavelength of the emitted light may refer to the median of the wavelength range of the emitted light, or it may be a wavelength of the emitted light selected according to the requirements. Taking red light as an example, the selected central wavelength may be 625 nm, or other wavelengths such as 620 nm and 640 nm. In practice, the refractive index of the cut-off filter film layer 103 for every color may be set according to the above-mentioned relational expression (I) and (II), to achieve the filtering function of light of every color, so that the wavelength range of the emergent light of every color that transmits through the cut-off filter film layer 103 is within the range of less than or equal to 15 μm from the central wavelength of the emitted light.

For example, the light-emitting layer 102 may emit red light, green light and blue light. The center wavelength of the wavelength range of the emitted red light is 625 nm, the center wavelength of the green light is 520 nm, the center wavelength of the blue light is 475 nm, the wavelength range of the blue light transmitting through the cut-off filter film layer 103 is controlled to be 475±15 nm, the wavelength range of the green light transmitting through the cut-off filter film layer 103 is controlled to be 520±15 nm, and the wavelength range of the red light transmitting through the cut-off filter film layer 103 is controlled to be 625±15 nm.

As mentioned above, the light emitted by the light-emitting layer 102 may also be other light, for example purple light and yellow light, and the like. By adopting the encapsulation layer, the transmitted light of every color may be controlled within the range of less than or equal to 15 nm from the central wavelength of the emitted light.

Certainly, in practice, the wavelength range of the emergent light of every color that transmits through the cut-off filter film layer 103 may also be set to a range in which the difference from the central wavelength of the emitted light is less than or equal to other nanometers, such as 10 nm, or a narrower wavelength range.

It should be noted that, the more the cut-off filter film layer 103 filters the emitted light, the narrower the wavelength range of the emergent light transmitting through the cut-off filter film layer 103, thus making the emitted light purer. That is, after the emitted light emitted by the different light-emitting elements 1021 of the same color, the smaller the wavelength difference between the emergent light, the less likely it is to be recognized by human eyes, so that the display quality of the display panel is further improved.

For example, in some embodiments, the wavelength range of the emitted light of every color transmitted through the cut-off filter film layer 103 may be set to satisfy the following condition: it is a range in which a difference from the central wavelength of the emitted light of this color is less than or equal to Sam. In this way, the color change may not be observed by human eyes, and the display quality may be further improved.

In some embodiments, the encapsulation layer further includes a composite adhesive layer 201, the composite adhesive layer 201 may be composed of a plurality of adhesive layers Stacked on each other, and the composite adhesive layer 201 may achieve the following functions:

On the one hand, the light-emitting element 1021 may be protected by the composite adhesive layer 201. On the other hand, the color display of the light emitted by the light-emitting element 1021 in the side view and the front view is corrected to make the light emitted by the emitting elements 1021 of R, G and B three color light more uniform in the front view and the side view. On another hand, the reflectivity of the metal wiring on the substrate 101 is reduced to shield the uneven wiring surface of the substrate 101, so that the display screen has better uniformity.

Referring to FIGS. 2 and 3, showing structural schematic diagrams of the display panel in some embodiments. As shown in FIGS. 2 and 3, the display panel includes a substrate 101, a light-emitting layer 102, and an encapsulation layer. In these embodiments, the encapsulation layer includes a composite adhesive layer located at a side of the light-emitting layer 102 facing away from the substrate, and the cut-off filter film layer 103 is located between the composite adhesive layer 2011 and the light-emitting layer 102, or located at a side of the composite adhesive layer 201 facing away from the light-emitting layer 102.

As shown in FIG. 2 and FIG. 3, the encapsulation layer includes a composite adhesive layer 201 and a cut-off filter film layer 103. As shown in FIG. 2, the cut-off filter film layer 103 is located at the side of the composite adhesive layer 201 facing away from the light-emitting layer 102. That is, the display panel sequentially stacks the light-emitting layer 102, the composite adhesive layer 201 and the cut-off filter film layer 103 in the sequence from close to substrate 101 to away from substrate 101

As shown in FIG. 3, the cut-off filter film layer 103 is located between the light-emitting layer 102 and the composite adhesive layer 201. That is, the display panel sequentially stacks the light-emitting layer 102, the composite adhesive layer 201 and the cut-off filter film layer 103 in the sequence from close to substrate 101 to away from substrate 101

No matter which positions the cut-off filter film layer 103 is located, the screening effect of the cut-off filter film layer 103 on the light emitted by the light-emitting element 1021 is capable to be achieved, so that the wavelength range of the emergent light transmitting through the cut-off filter film layer 103 is smaller than that of the emitted light.

In some embodiments, the composite adhesive layer includes at least one of a diffusion adhesive layer 105, a transparent adhesive layer 106 and a black adhesive layer 107 that are stacked. Wherein, under the condition that the composite adhesive layer includes the diffusion adhesive layer 105, the diffusion adhesive layer 105 is disposed close to the light-emitting layer 102.

As shown in FIGS., 2 and 3, the composite adhesive layer 201 may include a diffusion adhesive layer 105 and a black adhesive layer 107 that are stacked, and may also include a diffusion adhesive layer 108, a transparent adhesive layer 106 and a laminated black adhesive layer 107 that are stacked.

As shown in FIG. 2, when the cut-off filter film layer 103 is located at the side of the composite adhesive layer 201 facing away from the light-emitting layer 102, the composite adhesive layer 201 may include a diffusion adhesive layer 105, a transparent adhesive layer 106 and a black adhesive layer 107 that are stacked. In this case, the diffusion adhesive layer 105 is located at a side of the light-emitting layer 102 facing away from the substrate 101, the transparent adhesive layer 106 is located at a side of the diffusion adhesive layer 105 facing away from the substrate 101, and the black adhesive layer 107 is located at a side of the transparent adhesive layer 106 facing away from the substrate 101.

As shown in FIG. 3, in case that the cut-off filter film layer 103 is located between the light-emitting layer 102 and the composite adhesive layer 201, the composite adhesive layer 201 may include a diffusion adhesive layer 105 and a black adhesive layer 107 that are stacked. In this case, a first substrate layer 108 is disposed between the cut-off filter film layer 103 and the diffusion adhesive layer 105. The first substrate layer 108 may support the cut-off filter film layer, and a black adhesive layer 107 is disposed on the side of the diffusion adhesive layer 105 facing away from the substrate 101.

Certainly, in some embodiments, the composite adhesive layer 201 may also include a diffusion adhesive layer 105 and a transparent adhesive layer 106. It should be noted that, the diffusion adhesive layer 105 may be disposed close to the light-emitting layer 102.

It should be noted that, as shown in FIGS. 2 and 3, the encapsulation layer may further include a second substrate layer 104 disposed on the outermost layer, the second substrate layer 104 may be located at a side of the cut-off filter membrane layer facing away from the substrate 101 as shown in FIG. 2, or at a side of the black rubber layer 107 in the composite adhesive layer 201 facing away from the substrate 101 as shown in FIG. 3.

Wherein, the second substrate layer 104 is made of glass or PMMA, and the cut-off filter film layer is evaporated on a lower surface of the second substrate layer 104. Particularly, the cut-off filter film layer may be evaporated on the lower surface of the second substrate layer 104 by using a sol-gel coating apparatus. The sol-gel coating apparatus may be operated at room temperature and atmospheric pressure, has high film uniformity and controllable micro-structure. It is suitable for substrates with different shapes and sizes, consequently, the cut-off filter film layer with a high laser damage threshold may be obtained by controlling the formulation and preparation process.

In the present embodiment, the function of the diffusion adhesive layer 108 is to make the emitted light generated by the light-emitting layer 102 more uniform in the front view and side view. In the case that the light-emitting layer 102 generates a plurality of colors of emitted light, for example, the light-emitting layer 102 generates emitted light of three colors of red, green and blue (RGB), the diffusion adhesive layer 105 may avoid color difference caused by the viewing angle, so that the size and light type of the RGB three color light-emitting element 1021 at a beam angle of a large viewing angle are close to the same. Consequently, to avoid the color cast on the surface of the direct display screen with the change of viewing angle, that is, from the front view to the side view, the display screen changes from white to light red and to light cyan thereafter.

Generally speaking, the coordinate inflection point of viewing angle color cast appears at a large viewing angle of 50°˜60°. By means of light pattern analysis, this viewing angle color case phenomenon is related to the light pattern mismatch and asymmetry between LED bare chips (the light patterns are different due to the internal structural differences between R chip and GB chip). Consequently, the problem of color cast in front view and side view may be improved by the diffusion adhesive layer 105, and the color uniformity of the light emitted by the display device at various viewing angles may be ensured.

In some embodiments, the material of the diffusion adhesive layer includes TiO₂, which in practice may be TiO₂ powder.

In some other embodiments, the particle size of TiO₂ is larger than or equal to 10 nm and less than or equal to 300 nm. Particularly, in some examples, transparent silica gel may be selected as the matrix of the diffusion adhesive layer 105, and diffusive particles, for example TiO₂ powder, may be added. The particle size of the TiO₂ powder may be 10 nm˜300 nm, and the thickness may be 50 μm.

In the present embodiment, the transparent adhesive layer 106 is used as a supplementary layer of film thickness, and its thickness may be 100 μm. That is, the transparent adhesive layer 106 is used as thickness compensation to increase the thickness of the composite adhesive layer 201. The increase of the thickness of the composite adhesive layer 201 may protect the underlying light-emitting element 1021 from being exposed.

In the present disclosure, the black adhesive layer 107 may reduce the reflectivity of the metal wiring on the substrate 101, and realize shielding the uneven wiring surface of the substrate 101 at the same time, so that the display picture has better uniformity. In some embodiments, this black adhesive layer 107 is formed by mixing black carbon black particles into a transparent silica gel matrix, and the particle size ranges between 10 nm˜500 nm.

In some embodiments, this black adhesive layer 107 is formed by mixing black carbon black particles in a transparent silica gel matrix, and the particle size of the black carbon black particles ranges between 10 nm˜500 nm.

In some embodiments, in order to better protect the light-emitting element 1021, the thickness of the composite adhesive layer 201 is larger than that of the light-emitting element 1021. Particularly, the total thickness of the composite adhesive layer 201 may be set to be 150 μm˜175 μm, so that the firmness and wear resistance of the film layer may be enhanced. In this way, the light-emitting element 1021 may not be exposed due to the protection of the composite adhesive layer 201, so that the problems of erosion and wear are avoided.

The cut-off filter layer 103 will be described in detail as follows:

In some embodiments, the cut-off filter film layer 103 may be a whole layer design structure, that is, it is a complete film layer. In this case, the configurations of different filter areas may be the same, particularly, the materials of different filter areas may be the same, or both the materials and thicknesses are the same, and the adjacent filter areas may be close to each other. When the encapsulation layer is prepared, it may be realized in one preparation process. Referring to FIG. 4, schematically shows a top view schematic diagram of the display panel according to some embodiments. As shown in FIG. 4, the orthogonal projection of the cut-off filter film layer 103 on the substrate 101 covers the substrate 101 completely, wherein the cut-off filter film layer 103 may allow the emitted light of a plurality of light-emitting elements 1021 to transmit through.

The cut-off filter film layer 103 may cover the light-emitting layer 102 completely, that is, the cut-off filter film layer 103 may be a whole layer of regular film system. In some embodiments, the cut-off filter film layer 103 may be composed of a plurality of stacked sub-film layers (will be described in detail in the following embodiments). When a whole layer of regular film system is adopted, every sub-film layer prepared is a whole layer film system, so that the evaporation of the cut-off filter film layer 103 may be facilitated, and the process difficulty may be reduced.

The whole layer of the cut-off filter film 103 may cover all the light-emitting elements 1021, to filter the emitted light emitted by the whole light-emitting layer 102, that is, the cut-off filter film 103 may allow the emitted light emitted by all or portion of the light-emitting elements 1021 to transmit through. As mentioned above, under the condition that 10,000 light-emitting elements 1021 are encapsulated in the light-emitting layer 102, the red light emitted by 8,000 chips is allowed to transmit through the cut-off filter layer 103, that is, the light of some light-emitting elements 1021 is allowed to transmit through.

In some other embodiments, the configurations of the filter areas corresponding to different colors of emitted light may be different, that is, the materials and/or thicknesses of the filter areas corresponding to different colors of emitted light are different, for example, the materials or thicknesses of the filter areas corresponding to different colors of emitted light are different, or both the materials and thicknesses are different.

Wherein, one filter area may cover one light-emitting element, or cover a plurality of light-emitting elements 1021 of a same light-emitting color. Particularly, the orthographic projection of one of the plurality of filter areas on the substrate covers the orthographic projection of at least one of the plurality of light-emitting elements generate a same color on the substrate, to make the filter area filters the emitted light emitted by the light-emitting elements that covered by the filter area.

The orthogonal projection of the filter area on the substrate 101 may cover the orthogonal projection of at least one light-emitting element 1021 on the substrate 101, to make the filter area allows the emitted light emitted by the light-emitting element 1021 covered by this filter area to transmit through, but does not allow the emitted light emitted by the light-emitting element 1021 uncovered by this filter area to transmit through. That is, the cut-off filter film layer 103 may merely filter the emitted light of the light-emitting element 1021 covered by the filter area, and may not filter the emitted light of the light-emitting element 1021 not covered by the filter area.

In some embodiments, the orthogonal projection of one filter area on the substrate may cover one light-emitting element, and may also cover a plurality of light-emitting elements generate light of the same color, or may cover all light-emitting elements generate light of the same color.

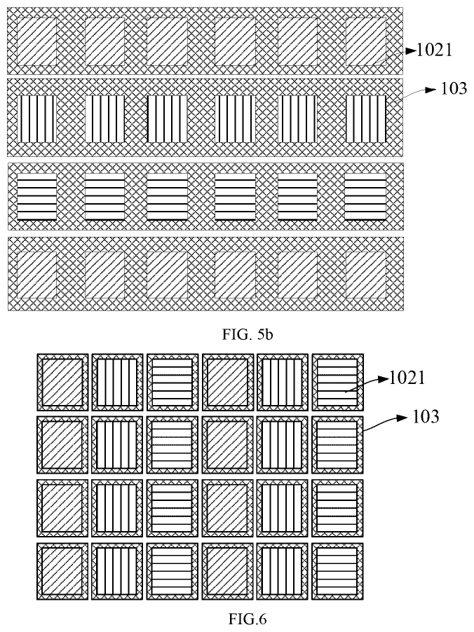

Referring to FIGS. 5 and 6, show top views of the display panel in some embodiments. As shown in FIGS. 5 and 6, taking the light-emitting layer 102 generates green light, red light and blue light as an example, wherein the light-emitting element 1021 includes an R chip (emits red light), a G chip (emits green light) and a B chip (emits blue light).

The cut-off filter film layer 103 includes a plurality of filter areas, and the orthogonal projections of the plurality of filter areas on the substrate 101 do not overlap with each other. The orthogonal projection of one filter area on the substrate 101 covers the orthogonal projection of at least one light-emitting element 1021 of the same color on the substrate 101, so that one filter area filters the emitted light of one color.

The orthographic projection of one filter area on the substrate 101 may cover the orthographic projection of one light-emitting element 1021 of a same color on the substrate 101, so that every light-emitting element 1021 has its own independent cut-off filter film, to achieve independent light screening of every light-emitting element 1021. Particularly, one filter area may filter the emitted light emitted by the light-emitting element 1021 covered by it, but does not filter the emitted light emitted by the light-emitting element 1021 not covered by it.

Alternatively, an orthographic projection of one filter area on the substrate 101 may cover the orthographic projection of all or portion of the light-emitting elements 1021 of a same color on the substrate 101. In this case, all or portion of the light-emitting elements 1021 emit the same color may be screened by the same cut-off filter film.

As shown in FIG. 5, one filter area covers all light-emitting elements 1021 of a same color. In this case, the plurality of light-emitting elements 1021 of every color may be arrange in array on the substrate 101, so that the light-emitting elements 1021 emit a same color are located in a row or a column. All the light-emitting elements 1021 in a row or a column perform targeted light screening on the light emitted by the light-emitting elements 1021 in the row or the column through respective independent cut-off filter films.

As shown in FIG. 6, one filter area covers one light-emitting element 1021. In this case, every light-emitting element 1021 has its own separate cut-off filter film. In this way, the plurality of light-emitting elements 1021 of every color may be arranged in array on the substrate 101, to make the light-emitting elements 1021 emits a same color are located in a row of a column. Alternatively, array arrangement is not required.

The cut-off filter film layer 103 includes a plurality of filter areas, and the orthogonal projections of these plurality of filter areas on the substrate 101 do not overlap with each other. Non-overlapping may refer to that no overlap exists between adjacent filter areas. In the case that no overlap between the orthogonal projections of the filter areas, the adjacent filter areas may be close to each other. That is, two adjacent filter areas may be in seamless contact. Alternatively, a space exists between the adjacent filter areas.

In some exemplary embodiments, a space may exist between the orthographic projections of the two adjacent filter areas on the substrate 101. As shown in FIG. 5a, FIG. 5b and FIG. 6, a space between the adjacent filter areas. Referring to FIG. 4, no gap exists between the adjacent filter areas.

Wherein, when a space exists between adjacent filter areas, a barrier material may be disposed between the adjacent filter areas, and the barrier material may prohibit the emitted light from transmitting through or allow portion of the emitted light to transmit through.

In the case that the orthographic projection of one filter area on the substrate 101 may cover the orthographic projection of one light-emitting element 1021 on the substrate 101, that is, in the case that one filter area covers one light-emitting element 1021, a space exists between the filter areas, this space may reserve a sufficient tolerance for preparing a separate filter area for every light-emitting element 1021, so that the difficulty of preparing a separate filter area for every light-emitting element 1021 is reduced. Particularly, referring to FIG. 6.

Certainly, in the case of the orthographic projection of one filter area on the substrate 101 covering the orthographic projections of a plurality of light-emitting elements 1021 have the same light-emitting color on the substrate 101, a space may also exist between the filter areas, and a sufficient preparing tolerance for the manufacturing tolerance may also be reserved to reduce the preparation difficulty. Particularly, referring to FIG. 5.

In case that one filter area covers one light-emitting element 1021, the relationship between the size of the filter area and the size of the light-emitting element 1021 may satisfy the following relational expression (III):

L≤x≤2L relational expression (III);
wherein L is the side length of the chip, and x is the size of the filter area. Particularly, as shown in FIG. 6, x may be the side length of the filter area.

Certainly, in case that the orthogonal projection of one filter area on the substrate 101 covers the orthogonal projection of a plurality of light-emitting elements 1021 of the same light-emitting color on the substrate 101, the size of the filter area may also be limited by using the above-mentioned relational expression (III). As shown in FIG. 5, in this case, x may represent the size in the direction from the R light-emitting element 1021 to the G light-emitting element 1021.

When this implementation method is adopted, because it includes a plurality of filter areas, every filter area may filter the emitted light of one color, and due to the wavelength range of the emitted light of every color is different, the wavelength range of the light transmitting through the cut-off filter film layer 103 may also be different. By disposing the filter area, the corresponding cut-off filter film layer 103 may be prepared separately for every color, so that targeted light filtering may be achieved. Compared with the method of preparing a whole film system, tit is less difficult to design the cut-off filter film layer 103 for the emitted light of every color separately. Consequently, more accurate light filtering may be achieved, making the emitted light purer.

In some embodiments, the cut-off filter film layer 103 needs to filter the emitted light emitted from the light-emitting layer 102, so that the wavelength range of the emergent light transmitting through the cut-off filter film 103 is narrower than the wavelength range of the emitted light. In some embodiments, the cut-off filter film layer 103 may include a plurality of sub-film layers disposed in a stacking manner, and every two adjacent sub-film layers have refractive indexes of different magnitudes.

Wherein, the cut-off filter film layer 103 may all be composed of a plurality of sub-film layers, whether the cut-off filter film layer 103 is the whole film system described above (the embodiment that a plurality of filter areas have the same configuration), or the embodiment that a plurality of filter areas have different configuration. Moreover, every two adjacent sub-film layers have different refractive indexes, that is, among the plurality of sub-film layers, every two adjacent sub-film layers may be alternately arranged with a high refractive index and a low refractive index. According to the above-mentioned relational expression (I) and (II), the refractive index of every sub-film layer may be designed, so that the emitted light of the light-emitting layer 102 may be filtered layer by layer by the plurality of sub-films, and finally the emergent light in the required waveband transmits through (the light transmits through the last sub-film layer of the cut-off filter layer is called emergent light).

When the light-emitting layer 102 generates a plurality of colors of emitted light, in case that a whole layer of cut-off filter film layer 103 is adopted (an embodiment that a plurality of filter areas have the same configuration), that is, the orthogonal projection of the cut-off filter film layer 103 on the substrate 101 covers the substrate 101 completely, the cut-off filter film layer 103 may filter the plurality of colors of emitted light at the same time.

In some embodiments, since the filter area includes a plurality of sub-film layers, wherein the side edges of the filter areas are aligned, that is, the side edges of every sub-film layer are flush. Alternatively, the side edge of the filter area is covered by one of the sub-film layers, for example the top sub-film layer.

The light filtering process is described with an exemplary example as below:

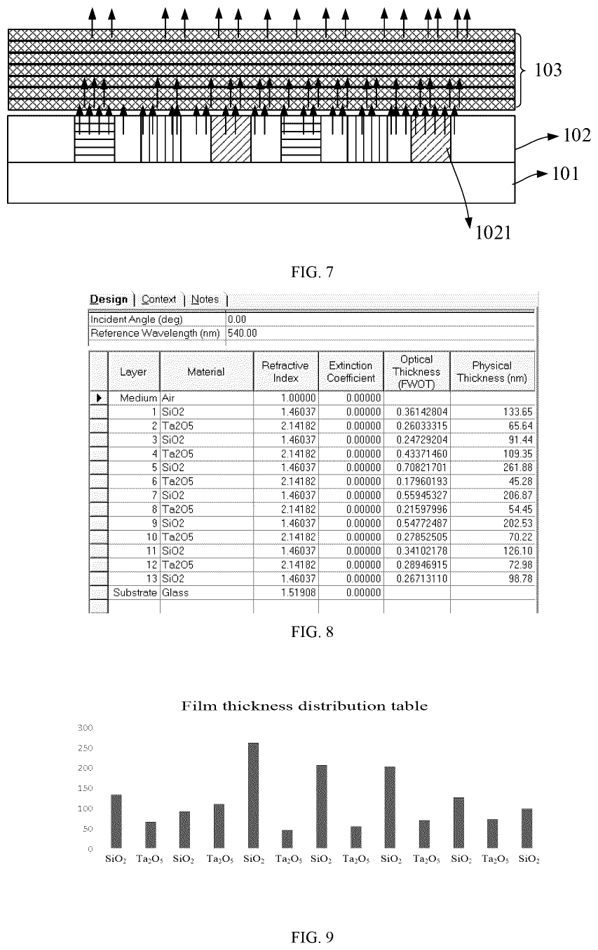

Referring to FIG. 7, showing a schematic diagram of the light filtering process of the cut-off filter film layer 103. Taking the emitted light of green light, blue light and red light generated by the light-emitting layer 102 as an example, a plurality of sub-film layers are stacked in the direction from close to the light-emitting element 1021 to far away from the light-emitting element 1021, and a total of k layers are designed, wherein the k is larger than or equal to 9 and less than or equal to 16.

Wherein, green light, blue light and red light generated by the light-emitting layer 102 enters the first layer, light of one wavelength is filtered out, for example, light with one wavelength of the green light is allowed to transmit through, that is, the light with this wavelength is reflected back, light with other wavelengths is allowed to transmit through. For example, the red light and blue light is allowed to transmit pass through, and these light allowed to transmit through the first layer enters the second layer, due to the refractive index of the second layer is different from that of the first layer, light with another wavelength is filtered out, and so forth, after transmitting through the plurality of sub-film layers, the red light, blue light and green light is filtered out on the corresponding sub-film layers, so that the wavelength range of the transmitted light is gradually narrowed. That is, the light of every color transmitting through the cut-off filter film layer 103 becomes purer.

In some embodiments, in the two adjacent sub-film layers, a refractive index of one sub-film layers is larger than 2, and a refractive index of the other sub-film layer is less than 2.

Wherein, the plurality of sub-film layers are alternately arranged with a high refractive index and a high refractive index. In this case, by means of simulation, it is found that a better filtering effect may be achieved, that is, the color of the emitted light may be purer when the plurality of sub-film layers are alternately arranged with a high refractive index and a high refractive index

Particularly, by means of simulation, it is found that, in the two adjacent sub-film layers, a refractive index of one sub-film layers is larger than 2, and a refractive index of the other sub-film layer is less than 2. Particularly, the refractive index difference between the sub-film layer with the refractive index larger than 2 and the sub-film layer with the refractive index less than 2 may be larger. For example, the refractive index difference may be set to be 0.5 or 0.8 that higher than 0.5, and particularly, 0.5, 0.6, 0.7 and 0.8 may be selected. Every difference is described in detail in the following specific embodiments.

It should be noted that, with regard to the setting of this refractive index, whether the cut-off filter film layer 103 covers the substrate 101 completely is adopted, or embodiments that filter areas have different configuration, different sub-film layers may be set to be corresponded to different refractive indexes. Moreover, the difference of refractive index between every two adjacent sub-film layers may be selected as 0.5, 0.6, 0.7 and 0.8.

In some embodiments, a number of the plurality of sub-film layers may be larger than or equal to 9 and less than or equal to 16.

Particularly, in case that a whole layer design, that is, the cut-off filter film layer 103 covers the substrate 101 completely is adopted, the number of the plurality of sub-film layers may be larger than or equal to 10 and less than or equal to 15. Preferably, the cut-off filter film layer 103 may be composed of 13 sub-film layers.

Particularly, in the case of the embodiments that different filter areas have different configuration, the filter areas corresponding to different colors of emitted light may be composed of different numbers of sub-film layers. In one example, the number of sub-film layers in the filter area corresponding to the emitted light with longer wavelength is larger than that of the emitted light with shorter wavelength. That is, the narrower the wavelength range, the less the number of sub-film layers in the filter area.

For example, the filter area corresponding to blue light may be composed of 9 sub-film layers, the filter area corresponding to green light may be composed of 14 sub-film layers, and the filter area corresponding to red light may be composed of 16 sub-film layers.

In some embodiment, different sub-film layers may have different thickness.

As shown in the above-mentioned relational expression (II), the refractive index is related to the wavelength and thickness. Consequently, when the wavelength is known, the refractive index may be set by changing the thickness, to achieve the required level of refraction of the emitted light of a certain wavelength. In practice, the thickness of every sub-film layer may be simulated by software according to the relational expression (I) and (II) and the actual filtering requirements.

Particularly, every sub-film layer may have its own thickness, so that the refractive index may be finely adjusted by changing the thickness even though the materials of the sub-film layers are the same. Consequently, fine filtering of light in the same wavelength range may be realized. Particularly, the content detailed in examples 1 and 2 may be referred to.

In the embodiment that the filter areas corresponding to different colors of emitted light are configured differently, the thickness of the filter area corresponding to the emitted light with longer wavelength is larger than that of the emitted light with shorter wavelength.

In the present embodiment, the longer the wavelength is, the larger the thickness is required under the same refractive index according to relational expression (II). Consequently, to achieve the same filtering effect, the longer the wavelength is, the larger the thickness may be. In this regard, the thickness of the filter area corresponding to the emitted light of a longer wavelength may be larger than that of the filter area corresponding to the emitted light of a shorter wavelength. For example, the thickness of the filter area for filtering blue light may be smaller than that of the filter area for filtering green light, and the thickness of the filter area for filtering green light may be smaller than that of the filter area for filtering red light.

Certainly, in some embodiments, the thickness of the filter area may also be achieved by setting the number of the sub-film layers in the filter area. In every two colors of emitted light, a number of sub-film layers in the filter area corresponding to the emitted light with a longer wavelength is larger than a number of the sub-film layers in the filter area corresponding to the emitted light with a shorter wavelength.

That is, the thickness of the corresponding filter area may be increased by increasing the number of sub-film layers. Particularly, as described in the above-mentioned embodiment, the filter area corresponding to the blue light may be composed of 9 sub-film layers, the filter area corresponding to the green light may be composed of 14 sub-film layers, and the filter area corresponding to the red light may be composed of 16 sub-film layers.

In some embodiments, since the thickness of every filter area may be different, the surface of the cut-off filter film layer is not flush. In this case, if the cut-off filter film layer is disposed close to the light-emitting element, that is, on a side of the light-emitting element facing away from the substrate 101, when the composite adhesive layer is prepared on a side of the cut-off filter film layer facing away from the substrate, the first substrate layer 108 may be first covered on the side of the cut-off filter film layer facing away from the substrate. As shown in FIG. 3, the upper surface of the cut-off filter film layer is flattened by the first substrate layer 108. Alternatively, a transparent adhesive layer may be covered on a side of the cut-off filter film layer facing away from the substrate, and the upper surface of this transparent adhesive layer is flush, and a composite adhesive layer may be prepared on a side of the transparent adhesive layer facing away from the substrate. Consequently, the step difference caused by different thicknesses of the filter areas may be made up, bubbles may be prevented from being generated at the step difference position, and the display quality of the display panel may be improved.

In some embodiments, the refractive index of matter mainly depends on the material, and the thickness may finely adjust the refractive index (for a nano-scale material, the thickness may affect the refractive index). As mentioned above, in every two adjacent sub-film layers in the embodiment of the present disclosure, the refractive index of one sub-film layer is larger than 2, and the refractive index of the other sub-film layer is less than 2. In this way, a material with a refractive index larger than 2 may be selected as a film material with a high refractive index, and a low material with a refractive index less than 2 may be selected as a film material with a low refractive index.

Particularly, whether the configuration of the plurality of filter areas is the same, or the configuration of the filter areas corresponding to the emitted light of different colors is different, in the two adjacent sub-film layers, the film material of one sub-film layers includes at least one of Ta₂O₅, TiO₃, TiO₂ and ZrO₂, and the film material of the other sub-film layer includes at least one of SiO₂, MgF₂, CeF₃, Al₂O₃ and Y₂O₃.

Wherein, the Chinese name of Ta₂O₅ is tantalum pentoxide, the Chinese name of TiO₃ is titanium trioxide, the Chinese name of TiO₂ is titanium dioxide, the Chinese name of ZrO₂ is zirconium dioxide, the Chinese name of SiO₂ is silicon dioxide, the Chinese name of MgF₂ is magnesium fluoride, the Chinese name of CeF₃ is cerium fluoride, the Chinese name of Al₂O₃ is aluminum oxide, and the Chinese name of Y₂O₅ is yttrium oxide.

Wherein, one sub-film layer is made of a film material with high refractive index, wherein the film material with high refractive index includes Ta₂O₅, TiO₃, TiO₂ and ZrO₂. In practice, one or more of Ta₂O₅, TiO₃, TiO₂ and ZrO₂ may optionally be selected.

Wherein, the other sub-film layer is made of materials with a low refractive index, including SiO₂, MgF₂, CeF₃, Al₂O₅, and Y₂O₃. In practice, one or more of SiO2, MgF2, CeF3, Al2O3 and Y2O3 may optionally be selected.

Wherein the refractive indexes of each of the materials are as follows:

The refractive index of Ta₂O₅ is n=2.14182, the refractive index of TiO₂ is 2.39, the refractive index of ZrO₂ is n=2.05, and the refractive index of TiO₂ is 2.39.

The refractive index of SiO₂ is n=1.46037, the refractive index of MgF₂ is n=1.38, the refractive index of CeF₃ is n=1.63, the refractive index of Al₂O₃ is n=1.65 and the refractive index of Y₂O₃ is n=1.8.

Wherein, whether a plurality of filter areas have the same configuration of the filter areas corresponding to different colors of emitted light have different configurations, they may be made of the above-mentioned film material. Wherein, in three adjacent sub-film layers of a plurality of sub-film layers, the film materials used in different sub-film layers may all be different, as long as the high and low refractive indexes are alternately stacked. For example, 9 sub-film layers exist, and according to the order from one side of the light-emitting layer 102 to far away from light-emitting layer 102, the film material of the first sub-film layer may be Ta₂O₅, the film material of the second sub-film layer may be SiO₂, the film material of the third sub-film layer may be TiO₂ the film material of the fourth sub-film layer may be MgF₂, and the film material of the fifth sub-film layer may be TiO₂. By analogy, the cut-off filter film layer 103 of 25 the present disclosure may be obtained by layer-by-layer evaporation as required.

In a preferred embodiment, in order to reduce the preparation difficulty, the cut-off filter film layer 103 may be composed of two film layer materials with different refractive indexes and good adhesion, so that the adhesion between adjacent sub-film layers is improved and it is not prone to warp, thereby the yield of the display panel is optimized.

Particularly, every two adjacent sub-film layers may be overlapped and laminated by this two film layer materials, so that a plurality of sub-film layers are formed.

In a particular implementation, the cut-off filter film layer 103 includes a first film layer material and a second film layer material with different refractive indexes, wherein one sub-film layer in every two adjacent sub-films is the first film layer material, and the other sub-film layer in every two adjacent sub-films is the second film layer material.

Particularly, the first film material may be any one of Ta₂O₅, TiO₃, TiO₂, and ZrO₂ mentioned above, or it may be one of the Dim materials with good adhesion. The second film material may be any one of SiO₂, MgF₂, CeF₃, Al₂O₃ and Y₂O₃, or it may be a film material with good adhesion.

In some exemplary embodiments, the first film material includes Ta₂O₅, and the second film material includes SiO₂. For example, in the case of the plurality of filter areas have the same configuration, the first film material includes Ta₂O₅, and the second film material includes SiO₂, and the number of sub-film layers of the plurality of filter areas may be consistent.

Alternatively in some other exemplary embodiments, the thickness of the filter areas corresponding to different colors of emitted light may be different, but the materials may be the same. In this case, the first film material may include TiO₂, and the second film material may include SiO₂.

Wherein, SiO₂ (silicon dioxide) has relatively stable chemical properties, high fire resistance, high temperature resistance, small thermal expansion coefficient, high insulation, corrosion resistance, piezoelectric effect, resonance effect and its unique optical characteristics. When preparing the sub-film layer, it may enhance its adhesion with other sub-film layers and improve the evaporation effect.

Wherein, Ta₂O₅ (Tantalum pentoxide) is mainly used as a material for manufacturing special optical glass with high refraction and low dispersion.

In some another embodiments, the two kinds of film materials contained in the filter areas corresponding to different colors of emitted light may also be different. For example, the light-emitting layer 102 emits red light, blue light and green light, for the filter area for red light, the two kinds of film layer materials adopted in the light filter area may be Ta₂O₅ and SiO₂, for the filter area for green light, the two kinds of film layer materials adopted in the light filter area may be Ta₂O₅ and SiO₂, and for the filter area for blue light, the two kinds of film layer materials adopted in the light filter area may be Ta₂O₅ and SiO₂.

Certainly, the above is merely an exemplary description, and does not represent a particular limitation to the present disclosure. In practice, the film material of every sub-film layer in ever filter area may be selected according to the light filtering requirements, which is not particularly limited herein.

The display panel of the present disclosure will be illustrated with several particular examples below.

### First Example

In the first Example, the orthogonal projection of the cut-off filter film layer on the substrate covers the substrate completely, and the emitted light of different colors corresponds to different filter areas, and the materials and thicknesses of these filter areas may be all the same. Consequently, it may be completed in a single composition process. The light-emitting layer generates blue light, green light and red light. Correspondingly, it includes a light-emitting element that emits blue light, a light-emitting element that emits green light and a light-emitting element that emits red light. Referring to FIG. 2, the display panel includes a substrate, a light-emitting layer located at a side of the substrate, a diffusion adhesive layer located at a side of the light-emitting layer facing away from the substrate, a transparent adhesive layer located at a side of the diffusion adhesive layer facing away from the substrate, a black adhesive layer located at a side of the transparent adhesive layer facing away from the substrate, a cut-off filter film layer located at a side of the black adhesive layer facing away from the substrate, and a second substrate layer located at a side of the cut-off filter film layer facing away from the substrate.

Wherein, for the cut-off filter film layer, Ta₂O₅ with a high refractive index and SiO₂ with a low refractive index are selected as the film layer materials. Wherein, the refractive index of SiO₂ is n=1.46037, the refractive index of Ta₂O₅ is n=2.14182. The second substrate layer is made of glass with a refractive index n=1.519, the sub-film layer attached to the second substrate layer is SiO₂, the thickness of the sub-film layer is 98.78 nm, the adjacent sub-film layer is Ta₂O₅ with a thickness of 72.98 nm, and the high and low refractive index film layers are alternately arranged, with a total of 13 layers, and the top layer is SiO₂ with a thickness of 133.65 nm.

By means of film layer simulation, the thickness and arrangement of materials in every layer may be shown in FIG. & and FIG. 9, and the total film thickness is 1542.17 nm. In FIG. 9, the Refractive index represents refractive index, the extinction coefficient represents attenuation coefficient of light, the Physical thickness represents optical thickness, and the unit is nanometer (nm).

As shown in FIG. 9, in the cut-off filter film layer, from the top layer to the bottom layer, that is, in the order that from the side close to the second substrate layer 104 to away from the second substrate layer 104, the first sub-film layer is SiO₂ with a thickness of 133.6 nm, and the second sub-film layer is Ta₂O₅ with a thickness of 65.64 mm; the third sub-film layer is SiO₂ with a thickness of 91.44 nm, and the fourth sub-film layer is Ta₂O₅ with a thickness of 109.35 nm; the fifth sub-film layer is SiO₂ with a thickness of 261.88 nm, and the sixth sub-film layer is Ta₂O₅ with a thickness of 45.28 nm: the seventh sub-film layer is SiO₂ with a thickness of 206.87 nm, and the eighth sub-film layer is Ta₂O₅ with a thickness of 54.45 mm; the ninth sub-film layer is SiO₂ with a thickness of 202.53 nm, and the tenth sub-film layer is Ta₂O₅ with a thickness of 70.22 nm; the eleventh sub-film layer is SiO₂ with a thickness of 126.10 nm, and the 12th sub-film layer is Ta₂O₅ with a thickness of 72.98 nm; the thirteenth sub-film layer is SiO₂ with a thickness of 98.78 nm.

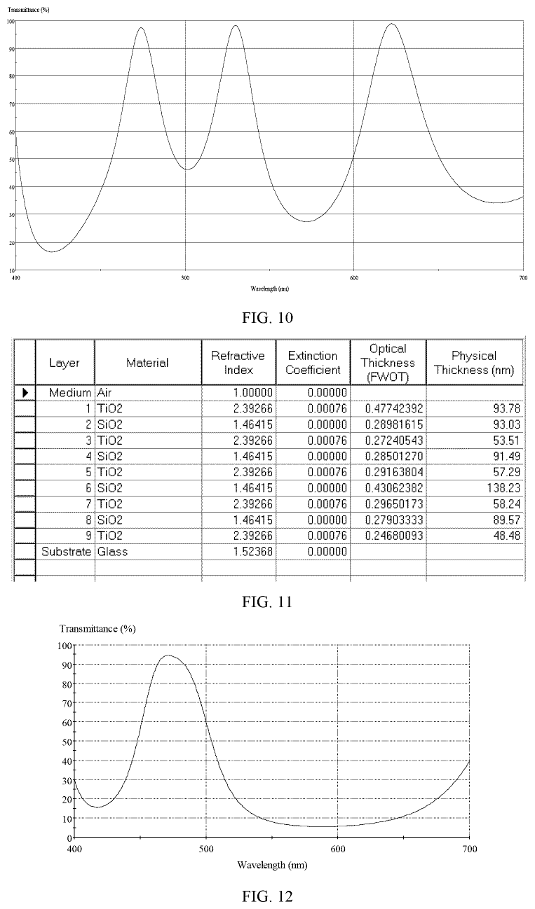

In this first example, the center wavelength of the blue light allowed to transmit through the cut-off filter film layer is (475±15) am, the center wavelength of the green light allowed to transmit through the cut-off filter film layer is (520±15) nm, and the center wavelength of the red light allowed to transmit through the cut-off filter film layer is (625±15) nm. The total thickness of the film layer is 1532 nm. The light transmittance curve of the film layer is shown in FIG. 10. In FIG. 10, the abscissa represents a wavelength, and the ordinate represents the light transmittance. It may be seen that, the light transmittance of the blue waveband is the highest in the range of 475±15 nm, and the light transmittance of other blue wavebands is very low. Consequently, the purity of the blue light may be improved. Similarly, the purity of the green light and red light is also improved.

### Second Example

The light-emitting layer generates blue light, green light and red light. Correspondingly, it includes a light-emitting element that emits blue light, a light-emitting element that emits green light, and a light-emitting element that emits red light.

As shown in FIGS. 5 and 6, every filter area filters the emitted light of one color, and a space may exist between adjacent filter areas.

As shown in FIG. 3, the display panel includes a substrate, a light-emitting layer located at a side of the substrate, a cut-off filter layer located at a side of the light-emitting layer facing away from the substrate, a first substrate layer located at a side of the cut-off filter layer facing away from the substrate, a diffusion adhesive layer located at a side of the first substrate layer facing away from the substrate, a black adhesive layer located at a side of the diffusion adhesive layer facing away from the substrate, and a second substrate layer located at a side of the black adhesive layer facing away from the second substrate layer.

Wherein, for the cut-off filter film layer, the film layer materials are adopted TiO₂ with a high refractive index, its refractive index is n=2.39, and SiO₂ with a low refractive index, its refractive index is n=1.46. The high and low refractive index layers are alternately arranged. Wherein, the blue light filter area has 9 sub-film layers, with a total thickness of 720 nm. Referring to FIG. 11, showing a thickness design distribution diagram of every sub-film layer in the blue light filter area.

As shown in FIG. 11, in this filter area, from the top layer to the bottom layer, that is, according to an order that from the side close to the second substrate layer 104 to away from the second substrate layer 104, the first sub-film layer is TiO₂ with a thickness of 93.78 nm, and the second sub-film layer is SiO₂ with a thickness of 93.03 nm; the third sub-film layer is TiO₂ with a thickness of 53.51 nm, and the fourth sub-film layer is SiO₂ with a thickness of 91.49 nm; the fifth sub-film layer is TiO₂ with a thickness of 57.29 nm, and the sixth sub-film layer is SiO₂ with a thickness of 138.23 nm; the seventh sub-film layer is TiO₂ with a thickness of 58.24 nm, and the eighth sub-film layer is SiO₂ with a thickness of 89.57 nm; the ninth sub-film layer is TiO₂ with a thickness of 48.48 nm.

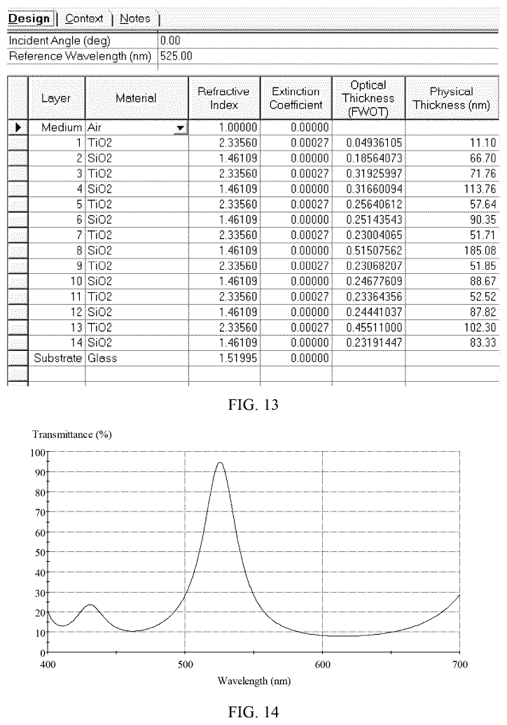

Referring to FIG. 12, showing a schematic diagram of the light transmittance of blue light after transmitting through the cut-off filter film layer.

Wherein, the filter area for filtering green light has 14 sub-film layers, with a total thickness of 1107 nm. Referring to FIG. 13, showing an arrangement diagram of the thickness and materials of each of the sub-film layers in the filter area for filtering green light in the cut-off filter film layer. Referring to FIG. 14, showing a schematic diagram of the light transmittance after green light transmitting through the cut-off filter film layer.

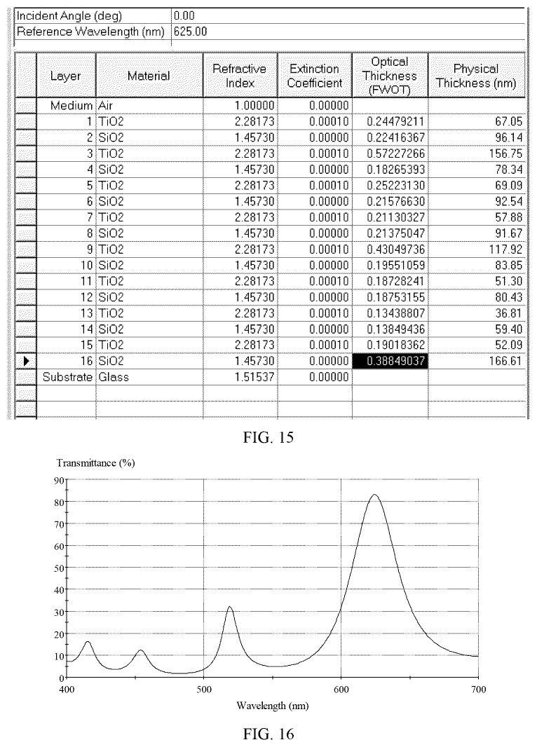

As shown in FIG. 13, in this filter area, from the top layer to the bottom layer, that is, according to an order from the side close to the second substrate layer 104 to away from the second substrate layer 104, the first sub-film layer is TiO₂ with a thickness of 11.10 nm, and the second sub-film layer is SiO₂ with a thickness of 66.70 mm; the third sub-film layer is TiO₂ with a thickness of 71.76 nm, and the fourth sub-film layer is SiO₂ with a thickness of 113.76 nm; the fifth sub-film layer is TiO₂ with a thickness of 57.64 nm, and the sixth sub-film layer is SiO₂ with a thickness of 90.35 nm; the seventh sub-film layer is TiO₂ with a thickness of 51.71 nm, and the eighth sub-film layer is SiO₂ with a thickness of 185.08 nm; the ninth sub-film layer is TiO₂ with a thickness of 51.85 nm, and the tenth sub-film layer is SiO₂ with a thickness of 88.67 nm; the eleventh sub-film layer is TiO₂ with a thickness of 52.52 nm, and the twelfth sub-film layer is SiO₂ with a thickness of 88.82 nm; the thirteenth sub-film layer is TiO₂ with a thickness of 102.30 nm, and the fourteenth sub-film layer is SiO₂ with a thickness of 83.33 nm.

Wherein, there are the filter area for filtering red light has 16 sub-film layers, with a total thickness of 1350 nm. Referring to FIG. 15, showing an arrangement diagram of the thickness and materials of each of the sub-film layers in the filter area for filtering red light in the cut-off filter film layer. Referring to FIG. 16, showing a schematic diagram of the light transmittance after red light transmitting through the cut-off filter film layer.

As shown in FIG. 15, in this filter area, from the top layer to the bottom layer, that is, according to an order that from the side close to the second substrate layer 104 to away from the second substrate layer 104, the first sub-film layer is TiO₂ with a thickness of 67.05 nm, and the second sub-film layer is SiO₂ with a thickness of 96.14 nm; the third sub-film layer is TiO₂ with a thickness of 156.75 nm, and the fourth sub-film layer is SiO₂ with a thickness of 78.34 nm; the fifth sub-film layer is TiO₂ with a thickness of 69.09 nm, and the sixth sub-film layer is SiO₂ with a thickness of 92.54 mm; the seventh sub-film layer is TiO₂ with a thickness of 57.88 nm, and the eighth sub-film layer is SiO₂ with a thickness of 91.67 nm; the ninth sub-film layer is TiO₂ with a thickness of 117.92 nm, and the tenth sub-film layer is SiO₂ with a thickness of 83.85 nm; the eleventh sub-film layer is TiO₂ with a thickness of 51.30 nm, and the twelfth sub-film layer is SiO₂ with a thickness of 80.43 nm; the thirteenth sub-film layer is TiO₂ with a thickness of 36.81 nm, and the fourteenth sub-film layer is SiO₂ with a thickness of 59.40 mmx; the fifteenth sub-film layer is TiO₂ with a thickness of 52.09 nm, and the sixteenth sub-film layer is SiO₂ with a thickness of 166.61 nm.

The advantages of the display panel of the present disclosure lie in:

On the one hand, the requirements for Bin classification of the light-emitting elements are reduced. Since the cut-off filter film layer performs light filtering on the emitted light, to make the difference between wavelengths of the light emitted by the light-emitting elements is narrower after it is transmitted, so that the purity and uniformity of the color of the light emitted from the display panel are improved, so that the light-emitting elements on the light-emitting layer may have a wider light-emitting waveband, and the requirements for Bin classification of the light-emitting elements is reduced.

In the second aspect, the yield of the light-emitting element is improved. Since the requirements on the fineness of Bin classification may be reduced, consequently. Bin classification with a coarse granularity may be allowed, and the light-emitting elements that are discarded in the light-emitting elements produced in the same batch are greatly reduced, so that production costs are reduced.

Based on the same inventive concept, the present disclosure provides a display device, which may include the display panel in any one of the above-mentioned embodiments.

Finally, it should be noted that in this disclosure, relational terms for example first and second are merely used to distinguish one entity or operation from another entity or operation, and do not necessarily require or imply any such actual relationship or order between these entities or operations. Moreover, the terms “include”, “comprise” or any other variation thereof are intended to cover a non-exclusive inclusion, so that a process, method, product or apparatus including a series of elements include not merely those elements, but also other elements not explicitly listed, or elements inherent to such process, method, commodity or equipment. In the absence of more restrictions, an element defined by the phrase “including one” does not exclude the existence of other same elements in the process, method, commodity or apparatus including the element.

A display panel and a display device provided by the present disclosure have been described in detail above, and the principle and implementation of the present disclosure have been expounded with specific examples in this context. The description of the above embodiments is merely used to help understand the method and core idea of the present disclosure. At the same time, according to the idea of the present disclosure, there will be changes in the specific implementation and application scope for a person skilled in the art. To sum up, the content of the description should not be understood as limitations to the present disclosure.

Other embodiments of the present disclosure will be apparent to a person skilled in the art from consideration of the description and practice of the invention disclosed herein. The present disclosure is intended to cover any variations, uses or adaptations of the present disclosure, which follow the general principles of this disclosure and include common general knowledge or customary technical means that are not disclosed in this disclosure. The description and examples are to be regarded as exemplary merely, with the true scope and spirit of the disclosure being indicated by the following claims.

It should be understood that, the present disclosure is not limited to the precise structure described above and shown in the drawings, and various modifications and changes may be made without departing from its scope. The scope of the present disclosure is limited merely by the appended claims.

Reference herein to “one embodiment”, “an embodiment” or “one or more embodiments” means that a particular feature, structure or characteristic described in connection with an embodiment is included in at least one embodiment of the present disclosure. In addition, please note that the word “in one embodiment” herein does not necessarily refer to the same embodiment.

In the description provided herein, numerous specific details are set forth. However, it is to be understood that, embodiments of the present disclosure may be practiced without these specific details. In some examples, well-known methods, structures and technologies have not been shown in detail so as not to obscure the understanding of this specification.

In the claims, any reference symbols located between parentheses shall not cause limitations on the claims. The word “comprise” does not exclude the presence of elements of steps not listed in a claim. The word “a” or “an” before an element does not exclude the presence of a plurality of such elements. The present disclosure may be realized by means of hardware including several different elements and by means of a suitably programmed computer. In the unit claims enumerating several devices, several of these devices may be embodied by a same hardware item. The use of word first, second, and third and the like does not indicate any order. These words may be interpreted as names.

Finally, it should be explained that, the above embodiments are merely used to illustrate the technical solution of the present disclosure, but not to limit it. Although the present disclosure has been described in detail with reference to the foregoing embodiments, a person skilled in the art should understand that, it is still possible to modify the technical solutions described in the foregoing embodiments, or to replace some technical features with equivalents. Moreover, these modifications or substitutions do not make the essence of the corresponding technical solutions deviate from the spirit and scope of the technical solutions of various embodies of the present disclosure.

1. A display panel, comprising:
a substrate, a light-emitting layer located at a side of the substrate, and an encapsulation layer located at a side of the light-emitting layer facing away from the substrate; the light-emitting layer comprises a plurality of light-emitting elements, and the encapsulation layer comprises a cut-off filter film layer; wherein the plurality of the light-emitting elements generate emitted light of at least two colors;
wherein, the cut-off filter film layer comprises a plurality of filter areas, and one filter area filters the emitted light of one color, so that a wavelength range of the emitted light transmitting through the filter area is narrower than that of emergent light.

2. The display panel according to claim 1, wherein the wavelength range of the emergent light of every color transmitting through the cut-off filter layer is a range in which a difference from the central wavelength of the emitted light of this color is less than or equal to 15 nm.

3. The display panel according to claim 1, wherein the orthogonal projection of the cut-off filter film layer on the substrate covers the substrate completely.

4. The display panel according to claim 1, wherein the orthogonal projections of the plurality of filter areas on the substrate do not overlap with each other.

5. The display panel according to claim 1, wherein the orthographic projection of one of the plurality of filter areas on the substrate covers the orthographic projection of at least one of the plurality of light-emitting elements generating a same color on the substrate, to make the filter area filters the emitted light emitted by the light-emitting elements that covered by the filter area.

6. The display panel according to claim 1, wherein a space exists between orthographic projections of the two adjacent filter areas on the substrate.

7. The display panel according to claim 1, wherein the cut-off filter film layer comprises a plurality of sub-film layers disposed in a stacking manner, and every two adjacent sub-film layers have refractive indexes of different magnitudes.

8. The display panel according to claim 7, wherein in the two adjacent sub-film layers, a refractive index of one sub-film layers is larger than 2, and a refractive index of the other sub-film layer is less than 2.

9. The display panel according to claim 7, wherein in the two adjacent sub-film layers, the film material of one sub-film layers comprises at least one of Ta₂O₅, TiO₃, TiO₂ and ZrO₂, and the film material of the other sub-film layer comprises at least one of SiO₂, MgF₂, CeF₃, Al₂O₃ and Y₂O₃.

10. The display panel according to claim 7, wherein the cut-off filter film layer comprises a first film layer material and a second film layer material with different refractive indexes, wherein one sub-film layer in every two adjacent sub-films is the first film layer material, and the other sub-film layer in every two adjacent sub-films is the second film layer material.

11. The display panel according to claim 10, wherein the first film material comprises Ta₂O₅, and the second film material comprises SiO₂.

12. The display panel according to claim 7, wherein a number of the plurality of sub-film layers is larger than or equal to 9 and less than or equal to 16.

13. The display panel according to claim 7, wherein in every two colors of emitted light, a number of the sub-film layers in the filter area corresponding to the emitted light with a longer wavelength is larger than a number of the sub-film layers in the filter area corresponding to the emitted light with a shorter wavelength.

14. The display panel according to claim 7, wherein the different sub-film layers have different thicknesses.

15. The display panel according to claim 1, wherein, in every two colors of the emitted light, the thickness of the filter area corresponding to the emitted light with a longer wavelength is larger than that of the emitted light with a shorter wavelength.

16. The display panel according to claim 1, wherein the encapsulation layer further comprises a composite adhesive layer located at a side of the light-emitting layer facing away from the substrate, and the cut-off filter film layer is located between the composite adhesive layer and the light-emitting layer, or located at a side of the composite adhesive layer facing away from the light-emitting layer.

17. The display panel according to claim 16, wherein the composite adhesive layer comprises at least one of a diffusion adhesive layer, a transparent adhesive layer and a black adhesive layer; wherein, under the condition that the composite adhesive layer comprises the diffusion adhesive layer, the diffusion adhesive layer is disposed close to the light-emitting layer.

18. The display panel according to claim 1, wherein the plurality of light-emitting elements comprise a light-emitting element that emits blue light, a light-emitting element that emits green light and a light-emitting element that emits red light.

19. The display panel according to claim 1, wherein the light-emitting element is a submillimeter light-emitting diode.

20. A display device, comprising the display panel according to claim 1.
